(19) United States
(12) Patent Application Publication
(10) Pub. No.: US 2026/0112405 A1
(43) Pub. Date: Apr. 23, 2026

(54) CLAMPING CIRCUIT FOR AN AMPLIFIER CIRCUIT IN A MEMORY SYSTEM

(71) Applicant: Micron Technology, Inc., Boise, ID (US)

(72) Inventors: Jun Tan, Weißenfeld (DE); Milena Tsvetkova Ivanov, Munich (DE); Christopher John Kawamura, Boise, ID (US); Martin Brox, München (DE)

(21) Appl. No.: 19/355,890

(22) Filed: Oct. 10, 2025

Related U.S. Application Data
(60) Provisional application No. 63/709,229, filed on Oct. 18, 2024.

(51) Int. Cl. G11C 11/4091; G11C 5/14; G11C 11/4096; G11C 11/56

(52) U.S. Cl. CPC G11C 11/4091; G11C 5/145; G11C 11/4096; G11C 11/565; G11C 2207/06

(57) ABSTRACT

Methods, systems, and devices for a clamping circuit for an amplifier circuit in a memory system are described. The amplifier circuit may be configured to amplify a difference between a first voltage conveyed by a first input node and a second voltage conveyed by a second input node, the first voltage associated with a state of a memory cell. The clamping circuit may be configured to halt amplification by the amplification circuit by modifying a voltage of a gate terminal of a transistor of the amplifier circuit.

### CROSS REFERENCE

The present Application for Patent claims priority to U.S. Patent Application No. 63/709,229 by Tan et al., entitled “CLAMPING CIRCUIT FOR AN AMPLIFIER CIRCUIT IN A MEMORY SYSTEM,” filed October 18, 2024, which is assigned to the assignee hereof, and which is expressly incorporated by reference in its entirety herein.

### TECHNICAL FIELD

The following relates to one or more systems for memory, including a clamping circuit for an amplifier circuit in a memory system.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports a clamping circuit for an amplifier circuit in a memory system in accordance with examples as disclosed herein.

FIG. 2 shows an example of circuitry that supports a clamping circuit for an amplifier circuit in a memory system in accordance with examples as disclosed herein.

FIG. 3 shows an example of a timing diagram that supports a clamping circuit for an amplifier circuit in a memory system in accordance with examples as disclosed herein.

FIG. 4 shows a block diagram of a memory system that supports a clamping circuit for an amplifier circuit in accordance with examples as disclosed herein.

FIG. 5 shows a flowchart illustrating a method or methods that support a clamping circuit for an amplifier circuit in a memory system in accordance with examples as disclosed herein.

### DETAILED DESCRIPTION

To read the logic state stored by a memory cell, a memory system may include an amplifier circuit (e.g., a local amplifier circuit, also referred to as a local input/output (LIO) amplifier circuit) that receives a pair of differential input voltages associated with the logic state and that amplifies a difference between the input voltages by modifying the output voltages of one or more output nodes. The amplifier circuit may draw current from at least one of the output nodes (e.g., in an amount that is related to the corresponding input voltage), which may be precharged to an initial value, thus reducing the voltage on that output node and amplifying the difference between the input voltages. But due to the configuration and operation of the amplifier circuit, the reduction in voltage on the output node may be in excess of that needed for next-stage circuitry (e.g., the amplifier may over-amplify the difference), which may result in excessive power consumption when the output node is precharged for the next amplification operation.

According to the designs and techniques described herein, the power consumption of an amplifier circuit may be reduced, among other advantages, by coupling the amplifier circuit with a clamping circuit that automatically halts amplification after a threshold amplification has been reached. In addition to other components, the clamping circuit may include a replica sub-circuit that mirrors a portion of the amplifier circuit and that modifies the gate voltage of a transistor of the amplifier circuit that controls amplification. The replica sub-circuit circuit may be designed so that modification of the gate voltage halts the amplification after the threshold amplification has been reached, thus preventing over-amplification.

In addition to applicability in memory systems as described herein, techniques for clamping an amplifier circuit may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by decreasing power consumption, among other benefits.

In addition to applicability in memory systems described herein, techniques for clamping an amplifier circuit may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may improve the security of electronic devices and systems by using less power relative to other solutions, among other benefits.

Features of the disclosure are illustrated and described in the context of systems and architectures. Features of the disclosure are further illustrated and described in the context of circuitry, timing diagrams, and flowcharts.

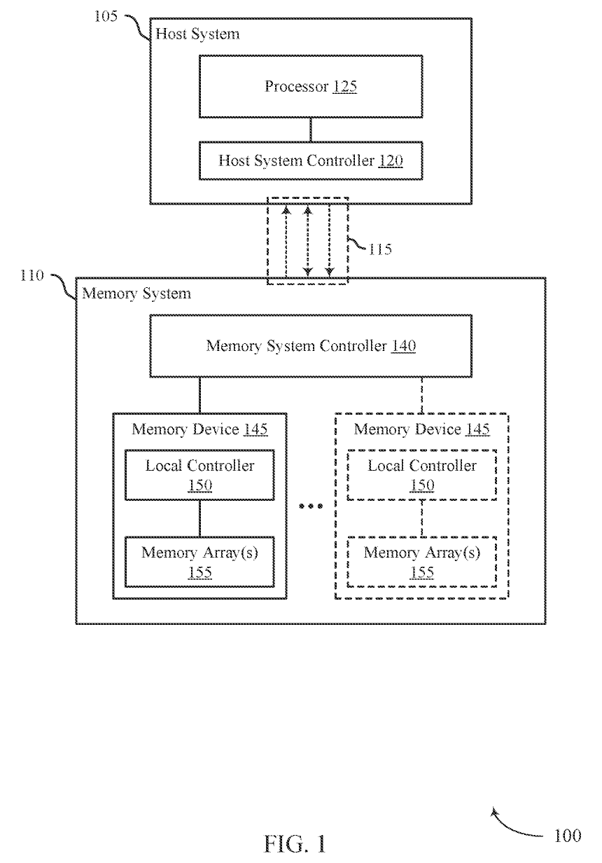

FIG. 1 illustrates an example of a system 100 that supports a clamping circuit for an amplifier circuit in a memory system in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

To read the logic states stored by memory cells in a memory device 145, the memory device 145 may include one or more amplifier circuits. For example, the memory device 145 may include a local amplifier circuit that receives differential voltages as inputs and that outputs (e.g., to a next-stage amplifier, such as a global input/output (GIO) amplifier circuit) corresponding output voltages with a difference that has been amplified. To amplify the difference and generate the output voltages, at least one of the output nodes of the amplifier circuit may be reduced from a precharged level. So, resetting the amplifier circuit may involve re-charging the output node(s) to the precharged level, which may consume power. But the amplifier circuit may be designed and operated such that the voltage of the output node(s) is reduced past a threshold voltage of the next-stage amplifier, resulting in over-amplification that consumes excess power during resetting, among other disadvantages.

According to the designs and techniques described herein, the power consumed by an amplifier circuit may be reduced, among other advantages, by adding a clamping circuit that automatically prevents over-amplification by the amplifier circuit. A sub-circuit of the clamping circuit may mirror a portion of the amplifier circuit but may be modified so that a control voltage that halts amplification by the amplifier circuit drops faster than the voltage(s) on the output node(s), thus “clamping” the voltage of the output nodes at a threshold level and preventing over-amplification.

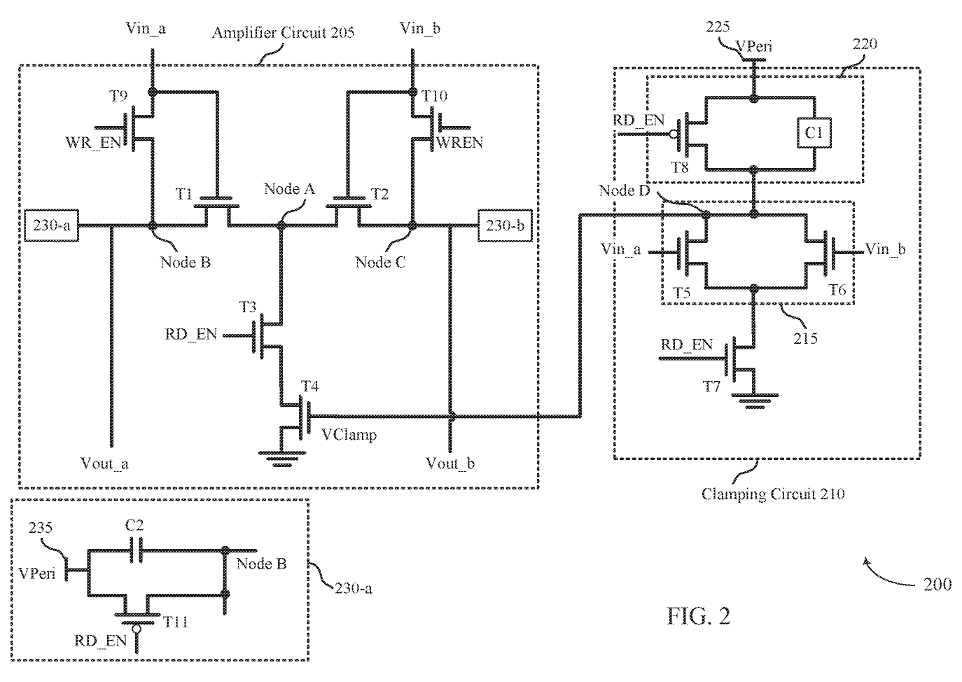

FIG. 2 illustrates an example of circuitry 200 that supports a clamping circuit for an amplifier circuit in a memory system in accordance with examples as disclosed herein. The circuitry 200 may include an amplifier circuit 205 and a clamping circuit 210. The amplifier circuit 205 may also be referred to as a transconductance-capacitance (Gm-C) integrator or other suitable terminology, and the clamping circuit 210 may also be referred to as a voltage clamping circuit, a control circuit, or other suitable terminology. The amplifier circuit 205 may generate output voltages Vout_a and Vout_b, the difference between which may be an amplified difference between the differential input voltages Vin_a and Vin_b. The clamping circuit 210 may output a control voltage, VClamp, that halts amplification by the amplifier circuit 205 after a threshold difference between Vout_a and Vout_b has been reached.

Before amplification, the output nodes (Node B, Node C) and the control node (Node D) may be precharged to a precharge level (e.g., VPeri, which may be supplied by the voltage supply 225 for the clamping circuit 210, or supplied by the voltage supply 235 for the sub-circuit 230-a, where Vperi is a same node for the clamping circuit 210 and the sub-circuit 230-a). During amplification, the amplifier circuit 205 may receive differential input voltages Vin_a and Vin_b (e.g., at the gate terminals of transistor T1 and transistor T2) and may reduce the voltage(s) on one or more of the output nodes (Node B, Node C) from the pre-charge level by an amount based on the corresponding input voltage. In this way, the difference between the output voltages Vout_a and Vout_b may represent an amplified difference between the input voltages Vin_a and Vin_b. The voltage(s) on the output nodes (Node B, Node C) may be reduced by activating transistor T3 and transistor T4 so that current is drawn from the output nodes (e.g., through transistor T3 and transistor T4 and one or more of transistor T1 and transistor T2) to the ground reference coupled with transistor T4.

Activating a transistor, also referred to as enabling or turning on a transistor, may refer to the biasing of the transistor so that current flows through the transistor. Deactivating a transistor, also referred to as disabling or turning off a transistor, may refer to biasing of the transistor so that current does not flow through the transistor.

To prevent over-amplification (e.g., excessive voltage reduction on the output node(s)), the clamping circuit 210 may modify (e.g., reduce) the control voltage VClamp on node D so that transistor T4 is deactivated, thus cutting off the current path between the output nodes (Node B, Node C) and the ground reference coupled with transistor T4. The control voltage VClamp may be reduced by activating transistor T7 so that that current is drawn (through transistor T5 and/or transistor T6) from Node D to the ground reference coupled with transistor T7. The selection of transistor T5, transistor T6, and other components of the clamping circuit 210 may be such that the reduction of the control voltage VClamp is faster than the reduction of the output nodes, thus preventing over-amplification. For example, the capacitive component C1 may have a first capacitive value that is different than a second capacitive value (e.g., the capacitive value of the capacitive component C2) associated with the amplifier circuit 205. In some cases, a control signal (e.g., the read enable (RD_EN) signal) may be in a low state, such that the output nodes (Node B, Node C) are not precharged to the precharge level (VPeri). In some such cases, the output nodes may not be precharged to the precharge level based on using the output nodes to write.

The amplifier circuit 205 may include transistor T1 and transistor T2, each of which may have a gate terminal coupled with a respective input node that conveys one of the differential input voltages (Vin_a, Vin_b). For example, transistor T1 may have a gate terminal that is coupled with the input node that conveys Vin_a, whereas transistor T2 may have a gate terminal that is coupled with the input node that conveys Vin_b. Vin_a may correspond to a logic state of a memory cell and Vin_b may be the complement of Vin_b, or vice versa. Transistor T1 and transistor T2 may each be coupled with node A, which in turn may be coupled with transistor T3. The gate of transistor T3 may be coupled with a control line that conveys a control signal (e.g., the read enable (RD_EN) signal) that controls (e.g., enables, disables) the amplifier circuit 205 and the clamping circuit 210. Transistor T3 may also be coupled with transistor T4, whose gate terminal may be coupled with node D, which conveys the control voltage VClamp that controls the activation status of transistor T4. Transistor T3 may be referred to as being in a cascade or series configuration with transistor T4.

The amplifier circuit 205 may also include sub-circuits 230, which may be used to set the output voltages (Vout_a, Vout_b) to a precharge level (e.g., VPeri). For example, the amplifier circuit 205 may include sub-circuit 230-a, which may be used to set the output voltage Vout_a to the precharge level, and may include sub-circuit 230-b, which may be used to set the output voltage Vout_b to the precharge level. Sub-circuit 230-a may include a capacitive component C2 coupled with a voltage supply 235 and node B. Sub-circuit 230-a may also include a transistor (e.g., transistor T11, which may be a p-type transistor) coupled with the voltage supply 235 and node B. The gate terminal of transistor T11 may be coupled with the control line that conveys the read enable (RD_EN) signal. Sub-circuit 230-b may be similarly configured.

The amplifier circuit 205 may also include transistors T9 and T10, which may be used during other (e.g., non-amplification) operations, such as a write operation. During an amplification operation, the transistors T9 and T10 may be deactivated (e.g., by reducing a control signal such as the write enable (WR_EN) signal) below the threshold voltages of the transistors T9 and T10).

The clamping circuit 210 may include transistor T5 and transistor T6, each of which may have a gate terminal coupled with one of the input nodes that conveys one of the differential input voltages (Vin_a, Vin_b). For example, transistor T5 may have a gate terminal that is coupled with the input node that conveys Vin_a, whereas transistor T6 may have a gate terminal that is coupled with the input node that conveys Vin_b. Transistor T5 and transistor T6 may each be coupled with transistor T7, which in turn may be coupled with a ground reference. The gate of transistor T7 may be coupled with the input node that conveys the read enable (RD_EN) signal.

In some examples, the sub-circuit 215 formed by transistor T5 and transistor T6 may be referred to as a replica circuit that mirrors the sub-circuit formed by transistor T1 and transistor T2. However, the transistors in sub-circuit 215 may be scaled (e.g., to support more current flow) relative to transistor T1 and transistor T2. In some examples (e.g., to achieve suitable scaling), the sub-circuit 215 may include additional transistors in series with transistor T5, additional transistors in series with transistor T6, or both. For example, a transistor whose gate terminal is coupled with the input node that conveys Vin_a may be in series with transistor T5 (such that a first terminal of the transistor is coupled with transistor T5 and a second terminal of the transistor is coupled with transistor T7). Additionally or alternatively, a transistor whose gate terminal is coupled with the input node that conveys Vin_b may be in series with transistor T6 (such that a first terminal of the transistor is coupled with transistor T6 and a second terminal of the transistor is coupled with transistor T7).

The clamping circuit 210 may also include transistor T8 and capacitive component C1, each of which may be coupled with voltage supply 225 and node D. The gate terminal of transistor T8 may be coupled with the input node that conveys the read enable (RD_EN) signal. The capacitive component C1 may be implemented as a metal-insulator-metal capacitor or a metal-oxide-metal (MOS) capacitor. Although shown with transistor T8 as a p-type transistor, transistor T8 may be implemented as an n-type transistor. In such cases, the gate terminal of transistor T8 may be coupled with a different node than the input node that conveys the read enable (RD_EN) signal, and a different control signal (e.g., a complement of read enable signal) may be used to control the activation status of transistor T8.

So, in some examples, the sub-circuit 220 formed by transistor T8 and capacitive component C1 may instead be formed by an n-type transistor (instead of the p-type transistor T8) and a MOS capacitor whose gate terminal is coupled with the voltage supply 225 and whose first and second terminals are each coupled with node D.

Before an amplification operation, the output nodes (Node B, Node C) may be precharged so that the output voltages Vout_a and Vout_b are precharged to a precharge level (e.g., VPeri). Further, node D may be precharged (e.g., to VPeri) so that the control voltage VClamp activates transistor T4. Node D may be precharged by activating transistor T8 (e.g., by decreasing the read enable (RD_EN) signal) so that node D charges from the voltage supply 225 through the capacitive component C1.

When the amplifier circuit 205 is enabled (e.g., by increasing the read enable (RD_EN) signal so that transistor T3 is activated), the voltage on one or more of the output nodes (Node B, Node C) may be reduced from the precharge level by sinking current through transistor T3 and T4 (and one or both of transistor T1 and transistor T2). For various performance reasons (e.g., to facilitate a reliable read operation), the read enable (RD_EN) signal may be relatively long, which may result in over-amplification absent the clamping circuit 210.

Increasing the read enable (RD_EN) signal to enable the amplifier circuit 205 may activate transistor T7 and may deactivate transistor T8, thus enabling the clamping circuit 210. In response to activation of transistor T7, current may be drawn from node D (e.g., through transistor T7 and one or more of transistor T5 and transistor T6) so that control voltage VClamp is reduced. Reducing the control voltage VClamp (e.g., below the threshold voltage of transistor T4) may deactivate transistor T4. Thus, node A (and therefor node B and node C) may be isolated from the ground reference, which may prevent further amplification. That is, current may cease flowing from the output node(s) (node B, node C), thus “clamping” the output voltages Vout_a and Vout_b.

Thus, the clamping circuit 210 may be used to automatically halt amplification by the amplifier circuit 205, which may prevent over-amplification, among other advantages.

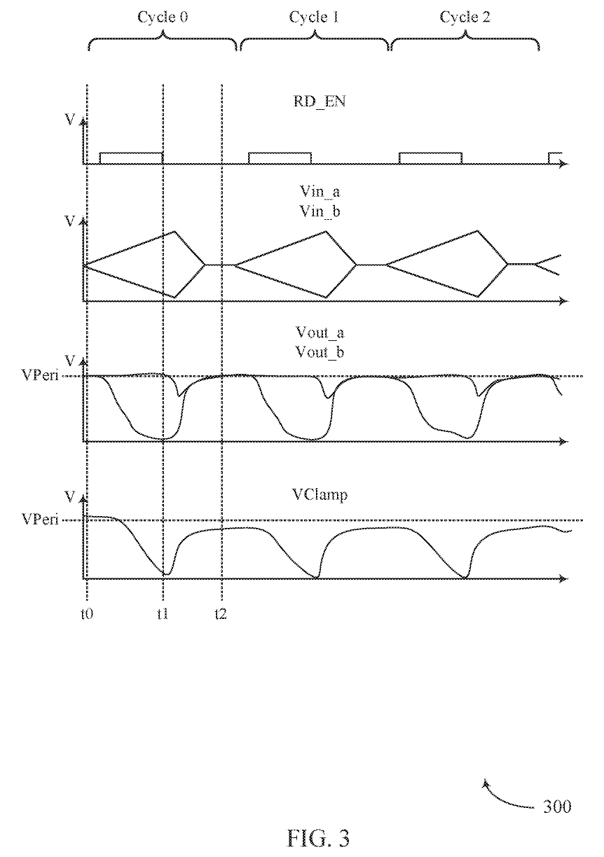

FIG. 3 shows an example of a timing diagram 300 that supports a clamping circuit for an amplifier circuit in a memory system in accordance with examples as disclosed herein. The timing diagram 300 may represent the voltages at various nodes of the circuitry 200 relative to time. For example, the timing diagram 300 may include: voltage V(RD_EN), which may be the voltage of the read enable (RD_EN) signal, input voltages Vin_a and Vin_b, output voltages Vout_a and Vout_b, and control voltage VClamp. Although shown with the same timing scale (on the x-axis), the voltage scale (on the y-axis) may be different across the timing diagrams.

The timing diagram 300 may illustrate three amplification cycles (e.g., cycle 0, cycle 1, cycle 2) each of which may include an read phase with RD_EN on (e.g., sometimes referred to as an amplification phase) and a standby phase with RD_EN off (e.g., sometimes referred to as a precharge phase). For brevity, one amplification cycle, cycle 0, is described. In cycle 0, time t0 and time t2 are generally related to a rising edge of the RD_EN signal, and time t1 is generally related to a falling edge of the RD_EN signal.

Also before time t0, the output voltages (Vout_a, Vout_b) may be set to a precharge level such as VPeri. For example, transistor T11 may be activated so that node B charges from the capacitive component C2, which may be charged by the voltage supply 235. Sub-circuit 230-b may be operated in a similar manner to set the output voltage Vout_b to the precharge level. Further, before time t0, the voltage on Node D (VClamp) may be set to the standby phrase, such that transistor T3, transistor T7, and transistor T8 are deactivated. In some cases, the read enable (RE_EN) signal may be low so that transistor T8 is activated and so that node D charges from the capacitive component C1, which may be charged by the voltage supply 225. In such cases, before time t0, transistor T3 and transistor T7 may be deactivated (because RD_EN is low), transistor T8 may be activated (because RE_EN is low), and transistor T4 may be activated (because VClamp is high).

At time t0, the read enable (RD_EN) signal may be increased so that the amplifier circuit 205 and the clamping circuit 210 are each activated. Also at time t0, the input voltages (Vin_a, Vin_b) may begin to diverge to their respective values.

Increasing the read enable (RD_EN) signal may activate transistor T3, transistor T7, and transistor T8 so that the output voltage (Vout_a, Vout_b) on at least one output node is decreased by sinking current through transistor T3 and transistor T4 (and one or both of transistor T1 and transistor T2). The decrease in the output voltage may be based on the difference between the input voltages (Vin_a, Vin_b). Increasing the read enable (RD_EN) signal may activate transistor T7 so that the voltage on node D (VClamp) is decreased by sinking current through transistor T7 (and one or both of transistor T5 and transistor T6). Due to different component parameters (e.g., different capacitive values for C1 and C2) between the amplifier circuit 205 and the clamping circuit 210, VClamp may decrease at a faster rate than the output voltage (Vout_a or Vout_b). Increasing the read enable (RD_EN) signal may also deactivate transistor T8, thereby enabling the reduction in VClamp.

At time t1, VClamp may decrease below the threshold voltage of transistor T4 so that transistor T4 is deactivated. Deactivation of transistor T4 may isolate node A from the ground reference, preventing additional reduction in the output voltage and halting amplification. Thus, the output voltage (Vout_a or Vout_b) may be automatically “clamped” at a level regardless of whether the read enable (RD_EN) signal is high or low. The difference between the output voltages (Vout_a and Vout_b) may represent an amplified difference between the input voltages (Vin_a and Vin_b) that can be used by next stage circuitry (e.g., a GIO amplifier). Clamping the output voltage (Vout_a or Vout_b) may reduce the power consumed during the precharge phase to precharge the output nodes to the precharge level.

At or after time t1, the read enable (RD_EN) signal may be decreased to initiate the precharge phase. Decreasing the read enable (RD_EN) signal may deactivate transistor T3 and transistor T7 and may activate transistor T8 so that node D charges from the capacitive component C1, which may be charged by the voltage supply 225. Thus, VClamp may be re-set (precharged) to a precharge level such as VPeri. Also during the precharge phase, transistor T11 may be activated so that node B charges from the capacitive component C2, which may be charged by the voltage supply 235. Sub-circuit 230-b may be operated in a similar manner to set the output voltage Vout_b to the precharge level.

Thus, the clamping circuit 210 may be used to automatically halt the amplification provided by the amplifier circuit 205, which may reduce the power consumption of the amplifier circuit 205, among other advantages.

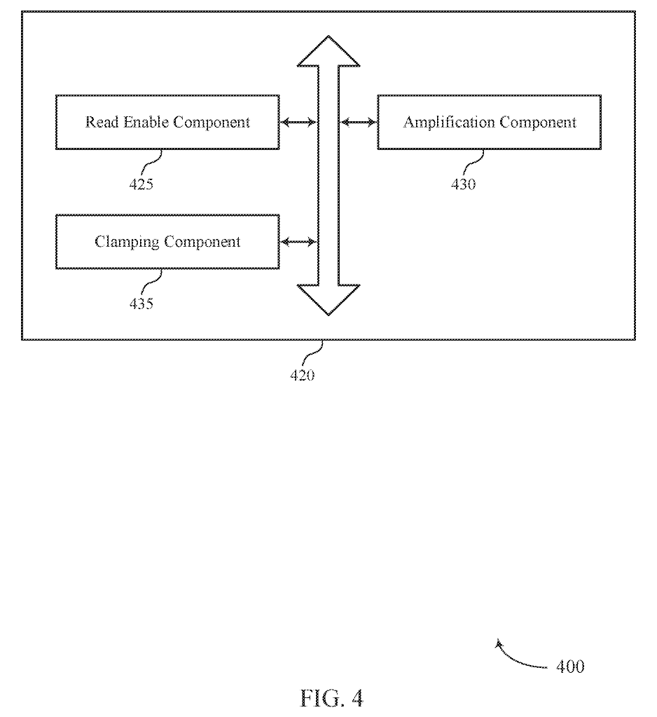

FIG. 4 shows a block diagram 400 of a memory system 420 that supports a clamping circuit for an amplifier circuit in accordance with examples as disclosed herein. The memory system 420 may be an example of aspects of a memory system as described with reference to FIGS. 1 through 3. The memory system 420, or various components thereof, may be an example of means for performing various aspects of clamping circuit for an amplifier circuit in a memory system as described herein. For example, the memory system 420 may include a read enable component 425, an amplification component 430, a clamping component 435, or any combination thereof. Each of these components, or components of subcomponents thereof (e.g., one or more processors, one or more memories), may communicate, directly or indirectly, with one another (e.g., via one or more buses).

The read enable component 425 may be configured as or otherwise support a means for increasing a read enable signal on a control line coupled with an amplifier circuit and a clamping circuit. The amplification component 430 may be configured as or otherwise support a means for amplifying, by the amplifier circuit based at least in part on increasing the read enable signal, a difference between a first voltage conveyed by a first input node of the amplifier circuit and a second voltage conveyed by a second input node of the amplifier circuit, the first voltage associated with a state of a memory cell. The clamping component 435 may be configured as or otherwise support a means for modifying, by a first transistor and a second transistor of the clamping circuit coupled with the amplifier circuit and based at least in part on increasing the read enable signal, a third voltage of a gate of a third transistor of the amplifier circuit, where modifying the third voltage deactivates the third transistor and halts amplification.

In some examples, the clamping component 435 may be configured as or otherwise support a means for activating, based at least in part on increasing the read enable signal, a fourth transistor of the clamping circuit that is coupled with the first transistor, the second transistor, and a ground reference, where the third voltage is modified based at least in part on activating the fourth transistor.

In some examples, the clamping component 435 may be configured as or otherwise support a means for deactivating a fourth transistor in parallel with a capacitive component and coupled with the first transistor, the second transistor, and the gate of the third transistor, where the third voltage is modified based at least in part on deactivating the fourth transistor.

In some examples, the fourth transistor is deactivated based at least in part on modifying the read enable signal. In some examples, the fourth transistor is deactivated based at least in part on modifying a control signal different than the read enable signal.

In some examples, the third voltage is modified from a precharge level, and the clamping component 435 may be configured as or otherwise support a means for activating a fourth transistor in parallel with a capacitive component and coupled with the first transistor, the second transistor, and the gate of the third transistor, where the third voltage is set to the precharge level based at least in part on activating the fourth transistor.

In some examples, the amplification component 430 may be configured as or otherwise support a means for activating a fourth transistor in cascade with the third transistor based at least in part on the read enable signal, where amplification is based at least in part on activating the fourth transistor.

In some examples, the amplification component 430 may be configured as or otherwise support a means for drawing current from an output node of the amplifier circuit through the third transistor and the fourth transistor as part of amplification, where drawing current from the output node reduces a fourth voltage on the output node of the amplifier circuit.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

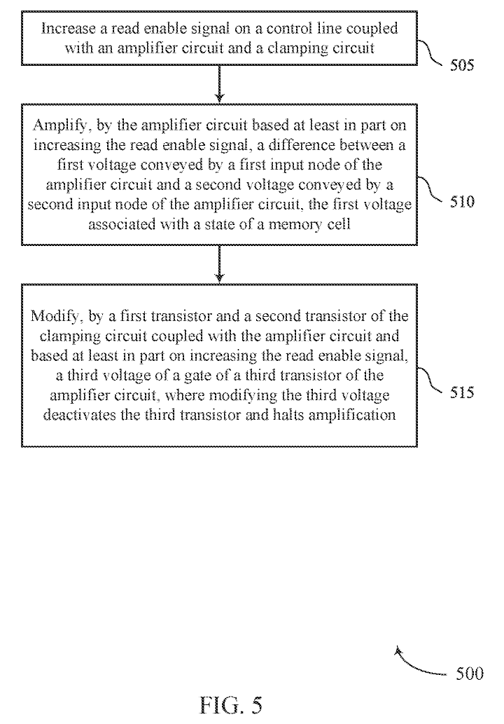

FIG. 5 shows a flowchart illustrating a method 500 that supports a clamping circuit for an amplifier circuit in a memory system in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include increasing a read enable signal on a control line coupled with an amplifier circuit and a clamping circuit. In some examples, aspects of the operations of 505 may be performed by a read enable component 425 as described with reference to FIG. 4.

At 510, the method may include amplifying, by the amplifier circuit based at least in part on increasing the read enable signal, a difference between a first voltage conveyed by a first input node of the amplifier circuit and a second voltage conveyed by a second input node of the amplifier circuit, the first voltage associated with a state of a memory cell. In some examples, aspects of the operations of 510 may be performed by an amplification component 430 as described with reference to FIG. 4.

At 515, the method may include modifying, by a first transistor and a second transistor of the clamping circuit coupled with the amplifier circuit and based at least in part on increasing the read enable signal, a third voltage of a gate of a third transistor of the amplifier circuit, where modifying the third voltage deactivates the third transistor and halts amplification. In some examples, aspects of the operations of 515 may be performed by a clamping component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for increasing a read enable signal on a control line coupled with an amplifier circuit and a clamping circuit; amplifying, by the amplifier circuit based at least in part on increasing the read enable signal, a difference between a first voltage conveyed by a first input node of the amplifier circuit and a second voltage conveyed by a second input node of the amplifier circuit, the first voltage associated with a state of a memory cell; and modifying, by a first transistor and a second transistor of the clamping circuit coupled with the amplifier circuit and based at least in part on increasing the read enable signal, a third voltage of a gate of a third transistor of the amplifier circuit, where modifying the third voltage deactivates the third transistor and halts amplification.

Aspect 2: The method, apparatus, or non-transitory computer-readable medium of aspect 1, further including operations, features, circuitry, logic, means, or instructions, or any combination thereof for activating, based at least in part on increasing the read enable signal, a fourth transistor of the clamping circuit that is coupled with the first transistor, the second transistor, and a ground reference, where the third voltage is modified based at least in part on activating the fourth transistor.

Aspect 3: The method, apparatus, or non-transitory computer-readable medium of any of aspects 1 through 2, further including operations, features, circuitry, logic, means, or instructions, or any combination thereof for deactivating a fourth transistor in parallel with a capacitive component and coupled with the first transistor, the second transistor, and the gate of the third transistor, where the third voltage is modified based at least in part on deactivating the fourth transistor.

Aspect 4: The method, apparatus, or non-transitory computer-readable medium of aspect 3, where the fourth transistor is deactivated based at least in part on modifying the read enable signal.

Aspect 5: The method, apparatus, or non-transitory computer-readable medium of any of aspects 3 through 4, where the fourth transistor is deactivated based at least in part on modifying a control signal different than the read enable signal.

Aspect 6: The method, apparatus, or non-transitory computer-readable medium of any of aspects 1 through 5, where the third voltage is modified from a precharge level and the method, apparatuses, and non-transitory computer-readable medium further includes operations, features, circuitry, logic, means, or instructions, or any combination thereof for activating a fourth transistor in parallel with a capacitive component and coupled with the first transistor, the second transistor, and the gate of the third transistor, where the third voltage is set to the precharge level based at least in part on activating the fourth transistor.

Aspect 7: The method, apparatus, or non-transitory computer-readable medium of any of aspects 1 through 6, further including operations, features, circuitry, logic, means, or instructions, or any combination thereof for activating a fourth transistor in cascade with the third transistor based at least in part on the read enable signal, where amplification is based at least in part on activating the fourth transistor.

Aspect 8: The method, apparatus, or non-transitory computer-readable medium of aspect 7, further including operations, features, circuitry, logic, means, or instructions, or any combination thereof for drawing current from an output node of the amplifier circuit through the third transistor and the fourth transistor as part of amplification, where drawing current from the output node reduces a fourth voltage on the output node of the amplifier circuit.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: An apparatus, including: an amplifier circuit configured to amplify a difference between a first voltage conveyed by a first input node and a second voltage conveyed by a second input node, the first voltage associated with a state of a memory cell; and a clamping circuit coupled with the amplifier circuit and configured to halt amplification, the clamping circuit including: a first transistor coupled with a gate terminal of a second transistor of the amplifier circuit and including a gate terminal coupled with the first input node, and a third transistor coupled with the gate terminal of the second transistor of the amplifier circuit and including a gate terminal coupled with the second input node, the third transistor, where the first transistor and the third transistor are configured to halt amplification by modifying a third voltage of the gate terminal of the second transistor.

Aspect 10: The apparatus of aspect 9, where the clamping circuit further includes: a fourth transistor coupled with the first transistor, the third transistor, and a ground reference.

Aspect 11: The apparatus of any of aspects 9 through 10, where the clamping circuit further includes: a capacitive component coupled with a voltage supply, the first transistor, the second transistor, and the third transistor; and a fourth transistor in parallel with the capacitive component, the capacitive component and the fourth transistor configured to modify the third voltage of the gate terminal of the second transistor to a precharge level.

Aspect 12: The apparatus of aspect 11, where the capacitive component includes a metal-insulator-metal capacitor or a metal-oxide-metal (MOS) capacitor.

Aspect 13: The apparatus of any of aspects 11 through 12, where the capacitive component includes a first capacitive value that is different than a second capacitive value associated with the amplifier circuit.

Aspect 14: The apparatus of any of aspects 9 through 13, further including: a control line coupled with the amplifier circuit and the clamping circuit and configured to convey a read enable signal that activates the amplifier circuit and the clamping circuit.

Aspect 15: The apparatus of any of aspects 9 through 14, where the first transistor and the third transistor are coupled with a fourth transistor of the clamping circuit and a fifth transistor of the clamping circuit, the apparatus further including: a first control line coupled with the amplifier circuit and the fourth transistor of the clamping circuit and configured to convey a read enable signal that activates the amplifier circuit and the clamping circuit; and a second control line coupled with the fifth transistor of the clamping circuit and configured to convey a control signal that activates the fifth transistor.

Aspect 16: The apparatus of any of aspects 9 through 15, where the amplifier circuit includes: a fourth transistor in cascade with the first transistor; a fifth transistor including a gate terminal coupled with the first input node, including a first terminal coupled with the fourth transistor, and including a second terminal coupled with a first output node; and a sixth transistor including a gate terminal coupled with the second input node, including a first terminal coupled with the fourth transistor, and including a second terminal coupled with a second output node, where the amplifier circuit is configured to amplify the difference by reducing a fourth voltage of the first output node or the second output node.

Aspect 17: The apparatus of any of aspects 9 through 16, further including: a fourth transistor coupled with the first transistor and including a gate terminal coupled with the first input node; and a fifth transistor coupled with the third transistor and including a gate terminal coupled with the second input node.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
an amplifier circuit configured to amplify a difference between a first voltage conveyed by a first input node and a second voltage conveyed by a second input node, the first voltage associated with a state of a memory cell; and
a clamping circuit coupled with the amplifier circuit and configured to halt amplification, the clamping circuit comprising:
a first transistor coupled with a gate terminal of a second transistor of the amplifier circuit and comprising a gate terminal coupled with the first input node, and
a third transistor coupled with the gate terminal of the second transistor of the amplifier circuit and comprising a gate terminal coupled with the second input node, the third transistor, wherein the first transistor and the third transistor are configured to halt amplification by modifying a third voltage of the gate terminal of the second transistor.

2. The apparatus of claim 1, wherein the clamping circuit further comprises:
a fourth transistor coupled with the first transistor, the third transistor, and a ground reference.

3. The apparatus of claim 1, wherein the clamping circuit further comprises:
a capacitive component coupled with a voltage supply, the first transistor, the second transistor, and the third transistor; and
a fourth transistor in parallel with the capacitive component, the capacitive component and the fourth transistor configured to modify the third voltage of the gate terminal of the second transistor to a precharge level.

4. The apparatus of claim 3, wherein the capacitive component comprises a metal-insulator-metal capacitor or a metal-oxide-metal (MOS) capacitor.

5. The apparatus of claim 3, wherein the capacitive component comprises a first capacitive value that is different than a second capacitive value associated with the amplifier circuit.

6. The apparatus of claim 1, further comprising:
a control line coupled with the amplifier circuit and the clamping circuit and configured to convey a read enable signal that activates the amplifier circuit and the clamping circuit.

7. The apparatus of claim 1, wherein the first transistor and the third transistor are coupled with a fourth transistor of the clamping circuit and a fifth transistor of the clamping circuit, the apparatus further comprising:
a first control line coupled with the amplifier circuit and the fourth transistor of the clamping circuit and configured to convey a read enable signal that activates the amplifier circuit and the clamping circuit; and
a second control line coupled with the fifth transistor of the clamping circuit and configured to convey a control signal that activates the fifth transistor.

8. The apparatus of claim 1, wherein the amplifier circuit comprises:
a fourth transistor in cascade with the first transistor;
a fifth transistor comprising a gate terminal coupled with the first input node, comprising a first terminal coupled with the fourth transistor, and comprising a second terminal coupled with a first output node; and
a sixth transistor comprising a gate terminal coupled with the second input node, comprising a first terminal coupled with the fourth transistor, and comprising a second terminal coupled with a second output node, wherein the amplifier circuit is configured to amplify the difference by reducing a fourth voltage of the first output node or the second output node.

9. The apparatus of claim 1, further comprising:
a fourth transistor coupled with the first transistor and comprising a gate terminal coupled with the first input node; and
a fifth transistor coupled with the third transistor and comprising a gate terminal coupled with the second input node.

10. A method, comprising:
increasing a read enable signal on a control line coupled with an amplifier circuit and a clamping circuit;
amplifying, by the amplifier circuit based at least in part on increasing the read enable signal, a difference between a first voltage conveyed by a first input node of the amplifier circuit and a second voltage conveyed by a second input node of the amplifier circuit, the first voltage associated with a state of a memory cell; and
modifying, by a first transistor and a second transistor of the clamping circuit coupled with the amplifier circuit and based at least in part on increasing the read enable signal, a third voltage of a gate of a third transistor of the amplifier circuit, wherein modifying the third voltage deactivates the third transistor and halts amplification.

11. The method of claim 10, further comprising:
activating, based at least in part on increasing the read enable signal, a fourth transistor of the clamping circuit that is coupled with the first transistor, the second transistor, and a ground reference, wherein the third voltage is modified based at least in part on activating the fourth transistor.

12. The method of claim 10, further comprising:
deactivating a fourth transistor in parallel with a capacitive component and coupled with the first transistor, the second transistor, and the gate of the third transistor, wherein the third voltage is modified based at least in part on deactivating the fourth transistor.

13. The method of claim 12, wherein the fourth transistor is deactivated based at least in part on modifying the read enable signal.

14. The method of claim 12, wherein the fourth transistor is deactivated based at least in part on modifying a control signal different than the read enable signal.

15. The method of claim 10, wherein the third voltage is modified from a precharge level, the method further comprising:
activating a fourth transistor in parallel with a capacitive component and coupled with the first transistor, the second transistor, and the gate of the third transistor, wherein the third voltage is set to the precharge level based at least in part on activating the fourth transistor.

16. The method of claim 10, further comprising:
activating a fourth transistor in cascade with the third transistor based at least in part on the read enable signal, wherein amplification is based at least in part on activating the fourth transistor.

17. The method of claim 16, further comprising:
drawing current from an output node of the amplifier circuit through the third transistor and the fourth transistor as part of amplification, wherein drawing current from the output node reduces a fourth voltage on the output node of the amplifier circuit.

18. A non-transitory computer-readable medium storing code, the code comprising instructions executable by processing circuitry of a memory system to cause the memory system to:
increase a read enable signal on a control line coupled with an amplifier circuit and a clamping circuit;
amplify, by the amplifier circuit based at least in part on increasing the read enable signal, a difference between a first voltage conveyed by a first input node of the amplifier circuit and a second voltage conveyed by a second input node of the amplifier circuit, the first voltage associated with a state of a memory cell; and
modify, by a first transistor and a second transistor of the clamping circuit coupled with the amplifier circuit and based at least in part on increasing the read enable signal, a third voltage of a gate of a third transistor of the amplifier circuit, wherein modifying the third voltage deactivates the third transistor and halts amplification.

19. The non-transitory computer-readable medium of claim 18, wherein the instructions are further executable by the processing circuitry to cause the memory system to:
activate, based at least in part on increasing the read enable signal, a fourth transistor of the clamping circuit that is coupled with the first transistor, the second transistor, and a ground reference, wherein the third voltage is modified based at least in part on activating the fourth transistor.

20. The non-transitory computer-readable medium of claim 18, wherein the instructions are further executable by the processing circuitry to cause the memory system to:
deactivate a fourth transistor in parallel with a capacitive component and coupled with the first transistor, the second transistor, and the gate of the third transistor, wherein the third voltage is modified based at least in part on deactivating the fourth transistor.
